(19) United States
(12) Patent Application Publication
(10) Pub. No.: US 2011/0175498 A1
(43) Pub. Date: Jul. 21, 2011

(54) Data Center

(76) Inventors: Cullen Bash, Los Gatos, CA (US); Chandrakant Patel, Fremont, CA (US)

(21) Appl. No.: 13/121,775

(22) PCT Filed: Sep. 30, 2008
(86) PCT No.: PCT/US08/78249

§ 371 Date: Mar. 30, 2011

(51) Int. Cl. H05K 5/02; B23P 11/00

(52) U.S. Cl. 312/107; 29/897

(57) ABSTRACT

A data center includes a mobile enclosure having an interior space. The interior space includes a first section and a second section, where the first section is separated from the second section by a first divider. The first section houses a rack having a first side and a second side, where the rack is positioned to separate the first section into a first aisle and a second aisle such that fluid flow between the first aisle and the second aisle is substantially prevented other than through the rack. The first aisle includes a fluid delivery device and the second aisle includes a fluid removal device, where the second section facilitates fluid communication between the fluid removal device and the fluid delivery device.

### BACKGROUND

Centralized communications and information technology (IT) data centers have been gaining ever-increasing popularity with the increased use of the Internet. In addition, the data centers are being constructed as relatively large static structures to house ever-increasing numbers of components to perform increased functions in hosting services for Internet Service Providers (ISPs), Application Service Providers (ASPs), and Internet Content Providers (ICPs).

Typical centralized data centers contain numerous racks of equipment that require cooling and wiring for power and communication connections. Once cooling system components and the power and communications wiring are in place, reconfiguration of the data centers is typically undesirable due to the costs and the time required to rearrange the cooling system components and the power and communications wiring. As such, it is often impractical from a cost standpoint to implement advances in IT performance, for instance, to more efficiently dissipate heat generated by the equipment, in the conventional data centers.

Mobile data centers have also been introduced to provide Internet access and other IT services on a temporary basis or in locations that otherwise do not have such services. The mobile data centers are typically formed in shipping containers or in trailers of trucks. One concern with forming mobile data centers is sufficiently provisioning cooling resources to adequately maintain the equipment within preset environmental condition levels.

One attempt at forming a mobile data center with sufficient cooling resources is described in U.S. Pat. No. 7,278,273 to Whitted et al., the disclosure of which is hereby incorporated by reference in its entirety. Whitted et al. attempts to increase the cooling provisioning by forming a computing module in one shipping container and forming a cooling module for cooling the computing module in a separate shipping container. As such, Whitted et al. requires that there be at least two separate shipping containers to provide the mobile data center, which increases costs and space requirements.

Another attempt that implements a trailer attached to a truck is described in U.S. Patent Application Publication Serial No. 2006/0082263, filed by Rimler et al., the disclosure of which is hereby incorporated by reference in its entirety. Rimler et al. depicts the racks of equipment as being arranged along a single line with an air conditioner and power supplies. Rimler et al. thus apparently discloses that the cooling provisioning provided by the air conditioner is able to dissipate heat generated by a relatively small number of equipment.

It would therefore be beneficial to have centralized communications and IT data centers that are readily reconfigurable to thus enable increased performance as advances in technology evolve or as changes in services performed in the data centers occur. It would also be beneficial to have mobile data centers that are both cost-effective and able to support relatively large numbers of equipment.

### BRIEF DESCRIPTION OF THE DRAWINGS

Features of the present invention will become apparent to those skilled in the art from the following description with reference to the figures, in which:

FIG. 1A shows a partially cut-away perspective view of a data center, according to an embodiment of the invention;

FIG. 1B shows a simplified side view of the data center depicted in FIG. 1A with an optional fan, according to an embodiment of the invention;

FIG. 1C shows a simplified side view of the data center depicted in FIG. 1A with an optional air conditioning unit, according to an embodiment of the invention;

FIG. 2A shows a simplified side view of the data center depicted in FIG. 1A, with the heat exchanger removed, and with an optional fan and an ambient air cooling system, according to an embodiment of the invention;

FIG. 2B shows a psychrometrics chart depicting the relationship between the dry bulb temperature and the wet bulb temperature of the ambient airflow at various locations with respect to the data center depicted in FIG. 2A, according to an embodiment of the invention;

FIG. 3 shows a block diagram of a cooling management system for managing cooling provisioning in the data center depicted in FIGS. 1A-1C and 2A, according to an embodiment of the invention;

FIG. 4 shows a flow diagram of a method for deploying a data center, according to another embodiment of the invention; and

FIG. 5 illustrates a computer system, which may be employed to perform various functions of the system manager depicted in FIG. 3, according to an embodiment of the invention.

### DETAILED DESCRIPTION OF THE INVENTION

For simplicity and illustrative purposes, the present invention is described by referring mainly to an exemplary embodiment thereof. In the following description, numerous specific details are set forth in order to provide a thorough understanding of the present invention. It will be apparent however, to one of ordinary skill in the art, that the present invention may be practiced without limitation to these specific details. In other instances, well known methods and structures have not been described in detail so as not to unnecessarily obscure the present invention.

Disclosed herein are data centers and a method of deploying data centers configured to support a relatively large number of components, such as, servers, in a relatively dense configuration. The data centers disclosed herein are able to support the larger number of components through use of, for instance, cooling system components and configurations that allow for relatively high rate of heat removal from the components. By way of particular example, the data centers disclosed herein are capable of supporting around 18 standard racks, with each rack supporting about 30 kW of power generation.

The data centers disclosed herein facilitate rapid and easy fabrication, transportation, and relocation of the data centers, to thereby facilitate changes due to, for instance, economic factors, business needs, convenience, environmental disasters, etc. In one regard, the data centers disclosed herein thus helps to make the reconfiguration and/or movement of a data center more cost effective and thus more economically feasible.

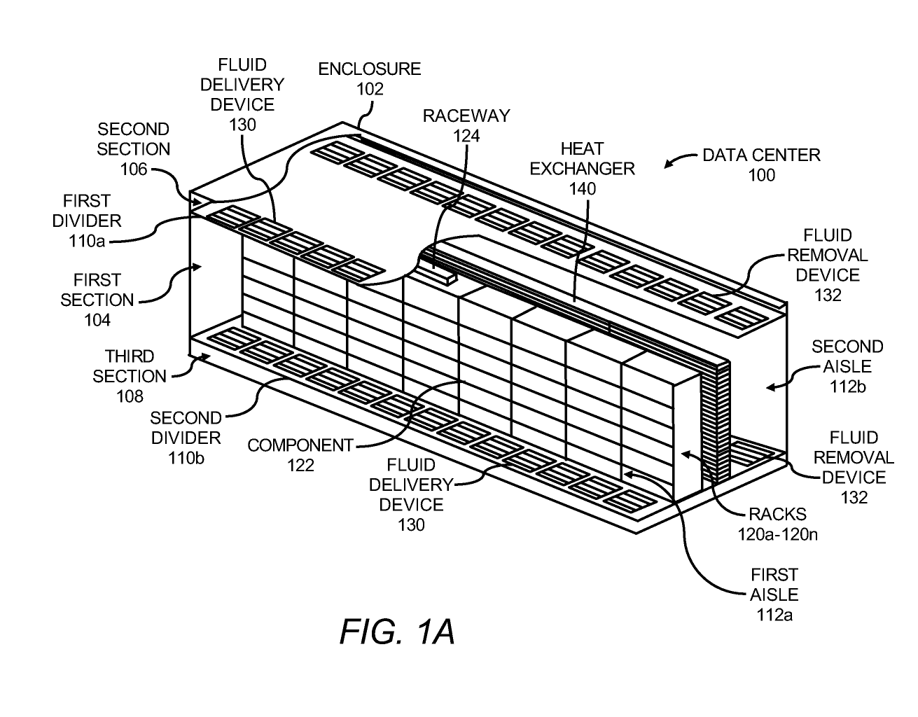

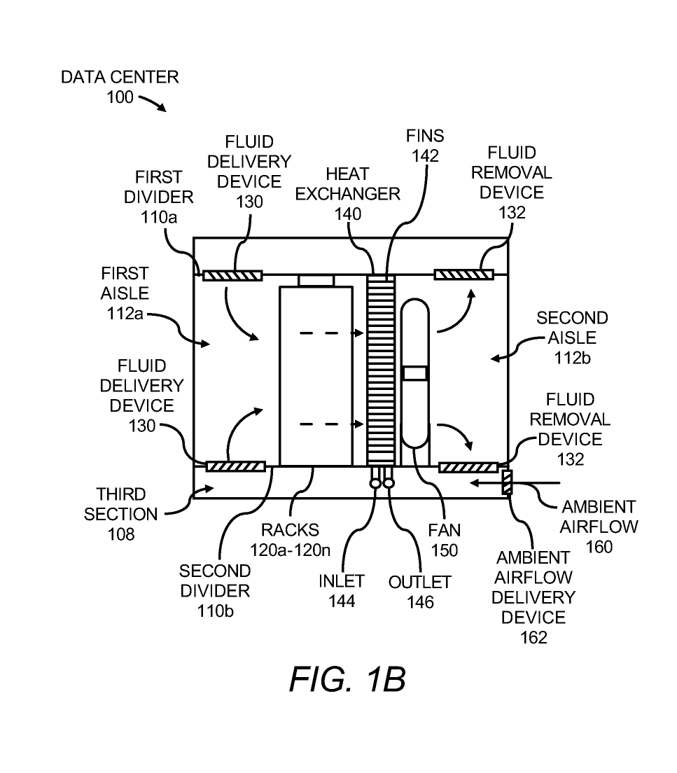

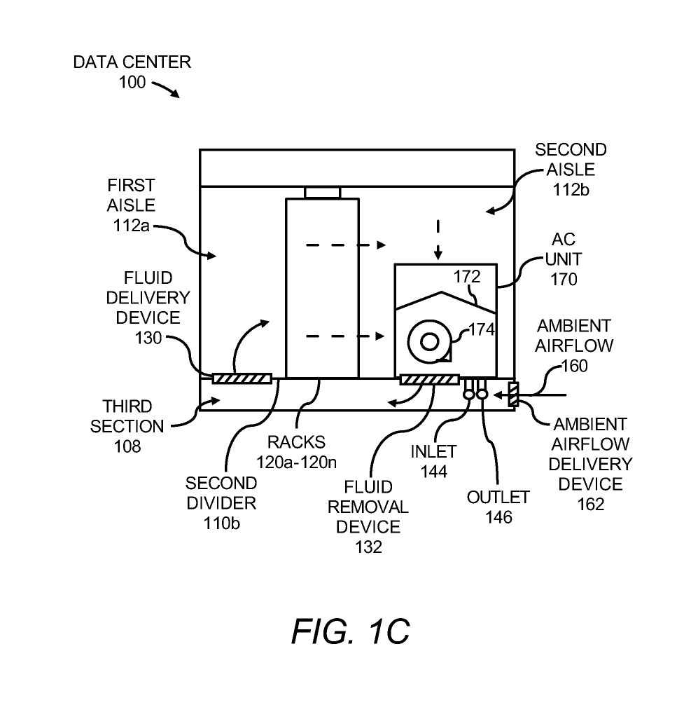

With reference first to FIG. 1A, there is shown a partially cut-away perspective view of a data center 100, according to an example. It should be understood that the data center 100 may include additional components and that some of the components described herein may be removed and/or modified without departing from a scope of the data center 100. By way of example, the data center 100 may include additional features such as, electric lights, switches, skylights, insulating material, etc.

As shown in FIG. 1A, the data center 100 is formed of an enclosure 102 having exterior walls that form the enclosure 102, where the enclosure is sufficiently large for human access. Although not explicitly shown in FIG. 1A, at least one of the exterior walls of the enclosure 102 includes a door to enable relatively easy access into and out of the enclosure 102. The door may be positioned and/or configured to enable an operator to access various areas of the enclosure 102, as well as, to enable insertion and removal of various components.

According to an example, the enclosure 102 comprises a standard shipping container, which has been modified to include the components discussed herein. According to another example, the enclosure 102 comprises a standard trailer, for instance, configured to be hauled by a tractor trailer truck. In other examples, the enclosure 102 comprises any other suitable container capable of housing a relatively large number of electronics racks, for instance, around 18 or more, and being moved from one location to another through use of various types of machinery.

With reference back to FIG. 1A, the enclosure 102 is also depicted as having an interior space, which has been divided into a plurality of sections. More particularly, the interior space is depicted as including a first section 104, a second section 106, and a third section 108. The second section 106 is separated from the first section 104 by a first divider 110a and the third section 108 is separated from the first section 104 by a second divider 110b.

The first section 104 is further divided into a first aisle 112a and a second aisle 112b by a plurality of racks 120a-120n. The racks 120a-120n generally comprise electronics cabinets configured to house components 122, such as, servers, power supplies, network switches, monitors, disk drives, etc. A raceway 124 housing wires for communications and power may be positioned on top of the racks 120a-120n, and may substantially close gaps between the tops of the racks 120a-120n and the first divider 110a.

Although FIG. 1A depicts a plurality of racks 120a-120n, it should be understood that the plurality of racks 120a-120n may be replaced with a single rack 120a that spans the distance across the interior space as occupied by the plurality of racks 120a-120n. In this regard, the racks 120a-120n may comprise commercially available electronics cabinets or the racks 120a-120n may comprise one or more customized electronics cabinets configured to house either standard or customized modular components 122.

The first aisle 112a may substantially be isolated from the second aisle 112b to substantially prevent fluid flow between the first aisle 112a and the second aisle 112b other than through the racks 120a-120n, and thus, through the components 122. The term “substantially” here is intended to denote that a vast majority of the fluid flow, for instance, greater than about 90% or more of the fluid flow from the first aisle 112a to the second aisle 112b occurs through the racks 120a-120n. According to an example, the flow may be restricted to enable such fluid flow by causing the racks 120a-120n to extend substantially the entire length and height of the first section 104. According to another example, the flow may be restricted through placement of other equipment, such as, power supplies, networking closet, etc., between the racks 120a-120n and an interior wall of the enclosure 102.

As also shown in FIG. 1A, a heat exchanger 140 is positioned in the second aisle 112b to cool cooling fluid flow exhausted from the components 122. The cooling fluid may comprise air or other fluid means for absorbing heat energy and transporting the heat energy from a location to another, thereby dissipating heat from the location.

The cooled fluid flow may be directed into either or both of the second section 106 and the third section 108 through fluid removal devices 132 respectively positioned in either or both of the first divider 110a and the second divider 110b. In addition, the cooled fluid flow may be delivered into the first aisle 112a from the second section 106 and the third section 108 through respective fluid delivery devices 130. Either or both of the fluid delivery devices 130 and the fluid removal devices 132 may comprise movable louvers that are configured to be repositioned to thereby vary either or both of the direction and the volume flow rate at which the cooling fluid flows through the fluid delivery devices 130 and the fluid removal devices 132. Various manners in which the heat exchanger 140 operates to cool the cooling fluid are described in greater detail herein below.

According to an example, a plurality of the components 122 include fans (not shown), whose operation causes the cooling fluid to circulate through the various sections 104-108 of the interior space in the enclosure 102. In another example, one or more fans (not shown) may be positioned at one or more locations in the enclosure 102 to cause the cooling fluid to circulate in the enclosure 102. By way of example, the one or more fans may be positioned in either or both of the first aisle 112a and the second aisle 112b, in either or both of the second section 106 and the third section 108, etc. The one or more fans may also form parts of either or both of the fluid delivery device 130 and the fluid removal device 132.

An example of a fan 150 positioned in the second aisle 112b is depicted in FIG. 1B, which is a simplified side view of the data center 100 depicted in FIG. 1A, according to an example. As also shown in FIG. 1B, cool fluid flow, represented by the solid arrows, flows into the modular components 122, and becomes heated, as represented by the dashed arrows. More particularly, as is generally known, the modular components 122 generate relatively large amounts of heat during their operation and the cooling fluid flow, such as, air, or other suitable gas, is supplied through the modular components 122 to absorb some of that heat and thus cool the modular components 122. The cooling fluid flow is supplied into the first aisle 112a through a plurality of fluid delivery devices 130, which are depicted as being positioned in the first divider 110a as well as the second divider 110b. It should, however, be understood that the cooling fluid may be supplied into the first aisle 112a through a single set of fluid delivery devices 130 positioned on either of the first divider 110a or the second divider 110b.

In any regard, the components 122 draw in the cooling fluid contained in the first aisle 112a through operation of internal fans and/or one or more external fans. In addition, the cooling fluid absorbs heat generated by heat generating devices, such as, processors, power supplies, disk drives, etc., contained in the modular components 122 and the heated cooling fluid is exhausted into the second aisle 112b. The heated cooling fluid flows through a heat exchanger 140 positioned directly in the flow path of the heated cooling fluid exhausted from the components 122. In addition, or alternatively, the heat exchanger 140 may be positioned in the first aisle 112a, such that, it cools the cooling fluid immediately prior to being supplied into the components 122.

The heat exchanger 140 is composed of a plurality of fins 142 and a series of pipes (not shown). The pipes are configured to enable a cooling medium, such as chilled water, water at reduced pressure, refrigerant, or other suitable cooling medium, to flow to various areas of the heat exchanger 140 and to cool the plurality of fins 142. More particularly, cooling medium at a relatively low temperature is supplied into the pipes of the heat exchanger through an inlet 144. The cooling medium absorbs heat collected by the fins 142 as the heated cooling fluid flows over the fins 142. The heated cooling medium is expelled from the pipes of the heat exchanger 140 through an outlet 146. The heated cooling medium may be cooled through operation of an air conditioning unit or other suitable mechanism for cooling the cooling medium.

According to an example, the fan 150 may be incorporated with the heat exchanger 140, such that the fan 150 and the heat exchanger 140 form a combination object.

In addition, or alternatively to the heat exchanger 140, ambient airflow 160 may be supplied into the cooling fluid supplied into the components 122 through an ambient airflow delivery device 162. As shown in FIG. 1B, the ambient airflow delivery device 162 is positioned in an exterior wall of the enclosure 102 and is positioned to supply ambient airflow into the third section 108. Although not shown, one or more fans may be positioned to cause the ambient airflow to be drawn into the third section 108.

According to an example, the ambient airflow delivery device 162 may be automatically controllable based upon one or more characteristics of the ambient airflow. For instance, the ambient airflow delivery device 162 may be closed when the temperature or the humidity of the ambient airflow exceeds predetermined values. Likewise, the ambient airflow delivery device 162 may be opened to allow ambient airflow 160 to be introduced into the cooling fluid when the temperature and/or humidity is favorable, for instance, below predetermined values.

According to an alternate example, the heat exchanger 140 and the fan 150 may be replaced with an air conditioning (AC) unit 170, as shown in FIG. 1C. The AC unit 170 may comprise cooling coils 172 and a blower 174. The cooling coils 172 receive cooling medium through an inlet 144 and operate to cool the heated cooling fluid supplied into the AC unit 170. The heated cooling medium is released from the AC unit 170 through an outlet 146, and may be cooled and re-supplied into the cooling coils 172 through the inlet 144. In addition, the blower 174 supplies the cooled cooling fluid into the third section 108, which is subsequently drawn into the components 122 through the fluid delivery device 130.

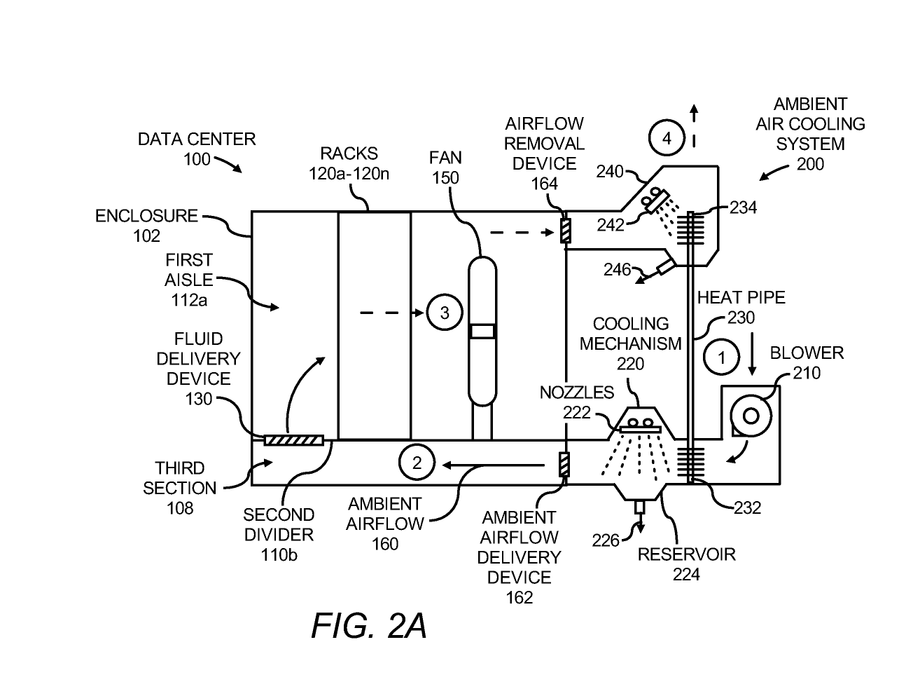

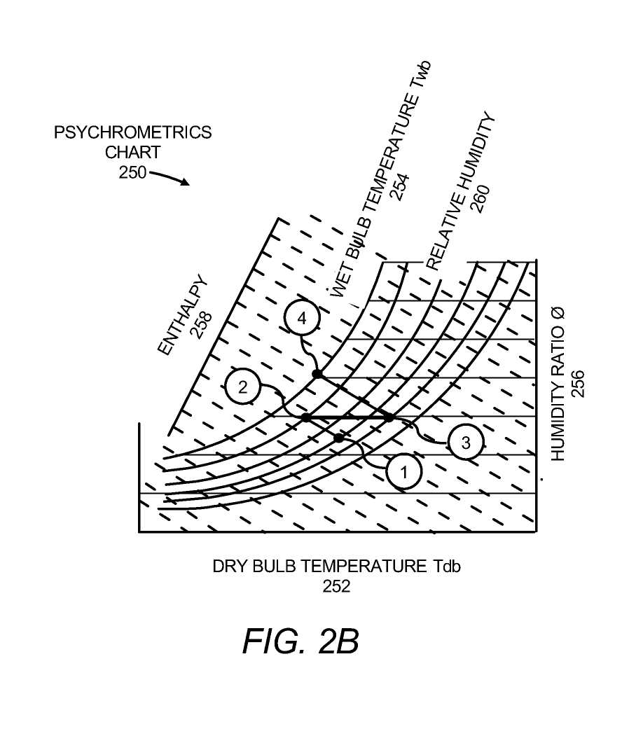

With reference now to FIG. 2A, there is shown a simplified side view of a data center 100, according to another example. The data center 100 depicted in FIG. 2A contains many of the same elements discussed with respect to FIGS. 1A-1C, and thus descriptions of those common elements are not repeated herein. Instead, those features that differ from FIGS. 1A-1C are discussed.

Most notably, the data center 100 depicted in FIG. 2A does not include a heat exchanger 140 or an AC unit 170. Instead, the data center 100 includes an ambient air cooling system 200 positioned adjacent to the enclosure 102 for cooling ambient airflow 160 supplied into an interior space of the enclosure 102. In one regard, the ambient air cooling system 200 may be employed in relatively cool, dry locations. It should, however, be understood that the ambient air cooling system 200 may be employed to cool the ambient airflow 160 supplied into any of the data centers 100 depicted in FIGS. 1A-1C to further reduce the temperature of the cooling fluid supplied into the components 122.

The ambient air cooling system 200 includes a blower 210 for drawing in ambient airflow and a cooling mechanism 220 for cooling the ambient airflow 160. The cooling mechanism 220 includes a number of nozzles 222 configured to spray water droplets into the ambient airflow supplied through the ambient airflow delivery device 162. The water droplets are collected in a reservoir 224 and conveyed back to the nozzles 222 as denoted by the arrow 226.

The ambient air cooling system 200 is also depicted as including additional means for cooling the ambient airflow 160. The additional cooling means includes a heat pipe 230 having a first end 232 and a second end 234. The first end 232 and the second end 234 are both illustrated as including fins for increasing the surface area over which heat transfer may occur. The first end 232 is positioned within the path of ambient airflow 160 prior to introduction into the interior of the enclosure 102.

The heat pipe 230 includes a cooling medium, such as, a phase-changing fluid configured to vaporize when heat is absorbed from the ambient airflow 160 in the first end 232, causing the cooling medium to travel toward the second end 234. As shown, the second end 234 is cooled through operation of a second cooling mechanism 240, which includes nozzles 242 and a reservoir 244. The nozzles 242 are configured to spray water droplets onto the second end 234 to remove heat from the vaporized cooling medium, which causes the cooling medium to condense and return back to the first end 232. Some of the water droplets are collected in the reservoir 244 and conveyed back to the nozzles 242 as denoted by the arrow 246. In addition, the airflow heated in the racks 120a-120n and exhausted through the airflow removal device 164 is caused to flow over the second end 234. The heated airflow operates to cool the cooling medium contained in the heat pipe 230 by increasing the evaporation of the water droplets from the second end 234. Although not shown, ambient airflow may also be supplied to evaporate water droplets from the second end 234 through a vent, for instance, located near the second end 234.

With particular reference now to FIG. 2B, there is shown a psychrometrics chart 250 depicting the relationship between the dry bulb temperature 252 and the wet bulb temperature 254 of the ambient airflow 160 at various locations (1-4) with respect to the data center 100 depicted in FIG. 2A, according to an example. It should be clearly understood that the data depicted in the psychrometrics chart 250 is merely an example and that the data may have any other suitable values without departing from a scope of the data center 100 discussed herein.

Generally speaking, the chart 250 depicts the water content in airflow supplied into the data center 100. The chart 250 may thus be employed to determine the suitability of the airflow for evaporative cooling. By way of example, if the water content is low, evaporative cooling by the airflow is considered to work very well. On the other hand, if the water content is high, the airflow is not considered to be suitable for evaporative cooling. In any regard, the chart 250 also depicts the humidity ratio 256, the enthalpy 258, and the relative humidity (RH) 260.

As shown in FIG. 2B, at point 1, which corresponds to the ambient airflow 160 prior to being drawn into the ambient air cooling system 200, the ambient airflow 160 has a first dry bulb temperature and a first wet bulb temperature. The ambient airflow 160 passes through or by either or both of the water droplets sprayed by the nozzles 222 and the first end 232 of the heat pipe 230 and thus its dry bulb temperature is reduced, but its wet bulb temperature is increased, as indicated at point 2.

The ambient airflow 160 is supplied through the components 122 and is exhausted at point 3, where its dry bulb temperature is increased. The ambient airflow 160 is exhausted out of the enclosure 102 and passes through or by either or both of the water droplets sprayed by the nozzles 242 and the second end 234 of the heat pipe 230 and thus its dry bulb temperature is reduced, but its wet bulb temperature is increased, as indicated at point 4.

Although the ambient air cooling system 200 has been depicted as being provided externally to the enclosure 102, it should be understood that some or all of the components forming the ambient air cooling system 200 may be positioned within the enclosure 102 without departing from a scope of the data center 100 disclosed herein.

By way of particular example, the ambient airflow supplied at point 1 may have a dry bulb temperature of 77° F. and a RH of 20%, which corresponds to a wet bulb temperature of 55° F. After moisture is supplied into the ambient airflow (point 2), the dry bulb temperature may be 65° F. and the RH may be 50%. After the airflow is heated (point 3), the airflow may have a dry bulb temperature of 100° F. and a RH of 15%. The relatively high temperature, low RH airflow is thus used to evaporate moisture from the second end 234 of the heat pipe 230, which causes the airflow to become fully saturated and have a dry bulb temperature of 70° F. (point 4).

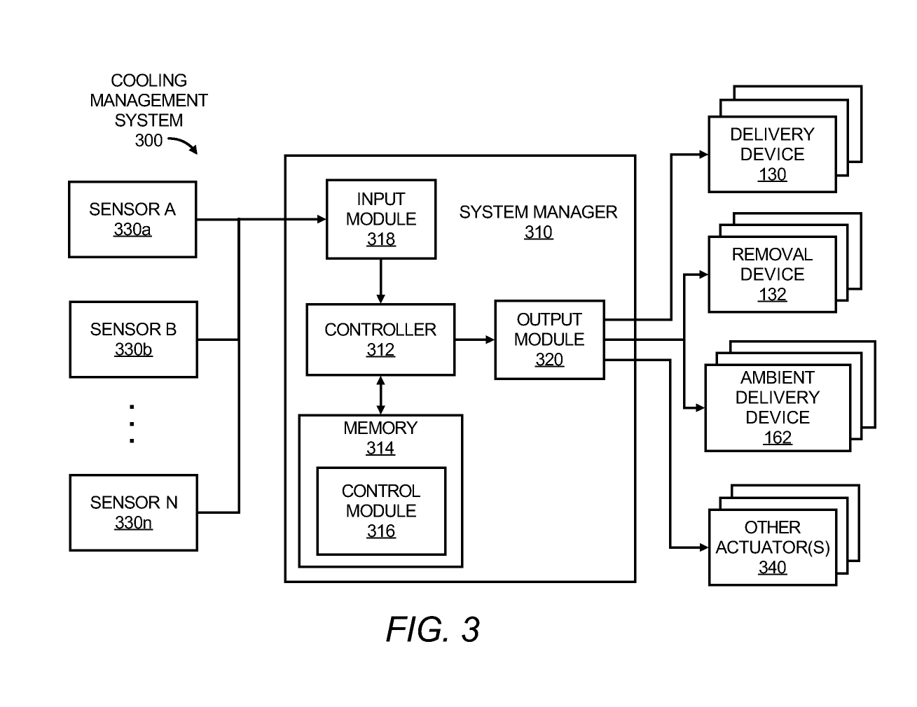

Turning now to FIG. 3, there is shown a block diagram of a cooling management system 300 for managing cooling provisioning in the data center 100 depicted in FIGS. 1A-1C and 2A, according to an example. It should be understood that the cooling management system 300 may include additional components and that some of the components described herein may be removed and/or modified without departing from a scope of the cooling management system 300.

Generally speaking, the cooling management system 300 may comprise an optional system for managing cooling in the data center 100. The cooling management system 300 may be considered to be optional because the system for cooling the components 122 in the data center 100 may be configured to function in a substantially static manner. In other words, the cooling medium flow through the heat exchanger 140 and the positioning of the louvers in the fluid delivery devices 130/fluid removal devices 132 may be set and maintained during operation of the components 122.

If implemented in the data center 100, the cooling management system 300 may vary one or more conditions, such as, temperature, volume flow rate, and flow direction of the cooling fluid, to achieve one or more goals. One goal may include, for instance, manipulating the supply of cooling fluid such that those components 122 generating greater amounts of heat receive greater amounts of cooling fluid to thereby substantially prevent formation of hot spots. Another goal may include varying the flow and/or temperature of the cooling medium supplied into the heat exchanger 140 based upon the conditions of the ambient airflow 160 supplied into the interior space of the enclosure 102. A further goal may be to place workloads among the components 122 to substantially prevent formation of hot spots. It should be understood that the following is merely a small sample of potential goals that the cooling management system 300 may seek to achieve and that achievement of any other suitable goal is within the scope of the cooling management system 300 discussed herein.

In any regard, as shown in FIG. 3, the cooling management system 300 includes a system manager 310, which generally comprises a computing device configured to perform various functions in the cooling management system 300. The system manger 310 includes a controller 312, which may comprise a microprocessor, a micro-controller, an application specific integrated circuit (ASIC), and the like, configured to perform various processing functions. In addition, or alternatively, the controller 312 may comprise software operating in any of a number of computing devices.

The system manager 310 may comprise a computing device and the controller 312 may comprise a microprocessor of the computing device. The controller 312 accesses a memory 314 configured to store software or algorithms that provide the functionality of the controller 312. In this regard, the memory 314 may comprise, for instance, volatile or non-volatile memory, such as DRAM, EEPROM, MRAM, flash memory, floppy disk, a CD-ROM, a DVD-ROM, or other optical or magnetic media, and the like.

The memory 314 includes a control module 316, which the controller 312 is configured to invoke or implement in controlling a plurality of actuators. The actuators may include actuators for varying the positions of louvers contained in the delivery devices 130, the removal devices 132, and the ambient delivery device 162. The actuators may also include other actuators 340 for controlling the speeds of the fans contained in the components 122 and/or the fan 150, actuators for controlling the temperature and/or the flow rate of cooling medium supplied through the heat exchanger 140, actuators for controlling the temperature and/or the flow rate of cooling fluid supplied through an AC unit 170, etc.

The control module 316 comprises software, hardware, or a combination thereof designed to identify which of the plurality of actuators is to be modulated in response to conditions detected by one or more sensors 330a-330n, where “n” is an integer greater than one, through an input module 318. The one or more sensors 330a-330n may comprise temperature sensors, workload sensors, etc., and the control module 316, when implemented or invoked, is configured to manipulate one or more of the plurality of actuators in various manners to achieve one or more of the goals discussed above based upon the detected temperatures/workloads.

The controller 312 may output commands through an output module 320. The input module 318 and the output module 320 may comprise any reasonably suitable hardware and software to enable the controller 312 to respectively communicate with the sensors 330a-330n and the actuators.

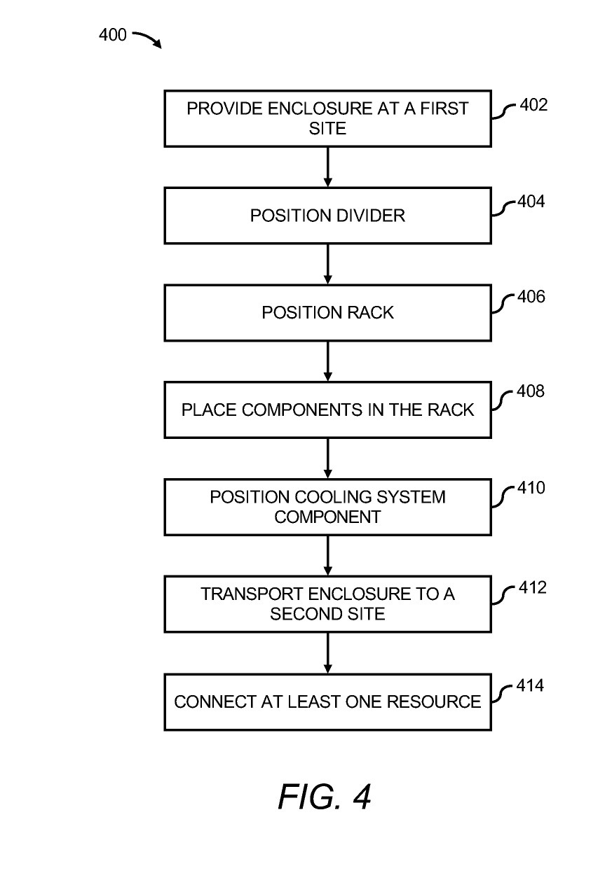

With reference now to FIG. 4, there is shown a flow diagram of a method 400 for deploying a data center, according to an example. It should be apparent to those of ordinary skill in the art that the method 400 represents a generalized illustration and that other steps may be added or existing steps may be removed, modified or rearranged without departing from a scope of the method 400.

The description of the method 400 is made with reference to the data center 100 illustrated in FIGS. 1A-1C and 2A, and thus makes reference to the elements cited therein. It should, however, be understood that the method 400 is not limited to the elements set forth in the data centers 100 depicted in those figures. Instead, it should be understood that the method 400 may be practiced in a data center having a different configuration than those depicted in FIGS. 1A-1C and 2A.

At step 402, an enclosure 102 is provided at a first site, such as, at a data center manufacturing facility. The enclosure 102 may comprise any of the containers discussed above, such as, a shipping container, a trailer, etc. In addition, the provided enclosure 102 includes at least one door that is sufficiently large for human access into the enclosure 102. The enclosure 102 itself is thus also sufficiently large for human access.

At step 404, a divider 110a/110b is positioned to split the enclosure 102 into a first section 104 and a second section 106. As shown in FIG. 1A, a first divider 110a may be positioned such that the second section 106 is near the top of the interior space in the enclosure 102. In addition, or alternatively, a second divider 110b may be positioned such that a third section 108 is positioned near the bottom of the interior space. In any case, the divider 110a/110b includes at least one fluid delivery device 130 near a first end of the divider 110a/110b and at least one fluid removal device 132 near a second end of the divider 110a/110b.

At step 406, at least one rack 120a-120n is positioned to separate the first section 104 into a first aisle 112a and a second aisle 112b, such that fluid flow from the first aisle 112a to the second aisle 112b is substantially prevented other than through the at least one rack 120a-120n. In addition, the at least one rack 120a-120n is positioned such that the fluid delivery device 130 is positioned in the first aisle 112a and the fluid removal device 132 is positioned in the second aisle 112b and the second section 106 and/or the third section 108 facilitates fluid communication between the fluid removal device 132 and the fluid delivery device 130.

At step 408, components 122, which may comprise modular components, are placed in the at least one rack 120a-120n, for instance, as shown in FIG. 1A. In addition, one or more cooling system components are positioned to cool the components 122, as indicated at step 410. The cooling system components may include, for instance, a heat exchanger 140, a fan 150, an ambient airflow delivery device 162, an AC unit 170, an ambient air cooling system 200, etc.

At step 412, the enclosure 102 containing the at least one rack 120a-120n and the one or more cooling system components may be transported to a second site, which differs from the first site. The second site may comprise, for instance, the location where the data center 100 is selected to be operated. Alternatively, however, the data center 100 may be fabricated at the second site.

At step 414, one or more resources are connected to at least one apparatus in the enclosure 102. The one or more resources comprise electricity, communications, water, etc. According to an example, a chilled water supply may be connected to a heat exchanger 140 or an AC unit 170.

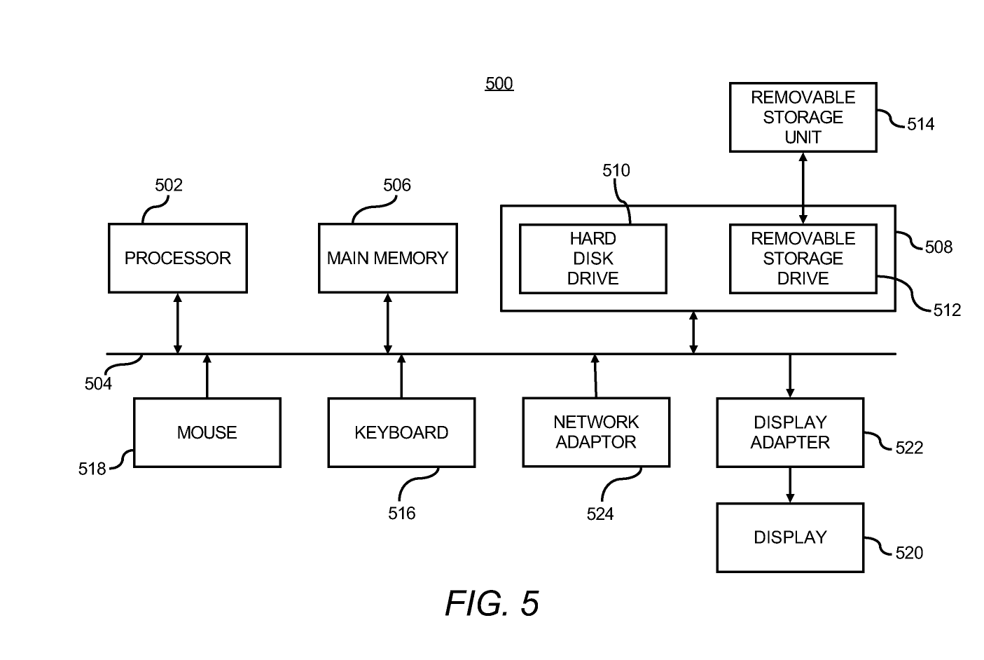

FIG. 5 illustrates a computer system 500, which may be employed to perform the various functions of the system manager 310 described herein above, according to an example. In this respect, the computer system 500 may be used as a platform for executing one or more of the functions described hereinabove with respect to the system manager 310.

The computer system 500 includes a processor 502, which may be used to execute some or all of the functions of the controller 312 discussed above. Commands and data from the processor 502 are communicated over a communication bus 504. The computer system 500 also includes a main memory 506, such as a random access memory (RAM), where the program code for, for instance, the controller 312, may be executed during runtime, and a secondary memory 508. The secondary memory 508 includes, for example, one or more hard disk drives 510 and/or a removable storage drive 512, representing a floppy diskette drive, a magnetic tape drive, a compact disk drive, etc., where a copy of the program code for efficiently cooling a structure may be stored.

The removable storage drive 512 reads from and/or writes to a removable storage unit 514 in a well-known manner. User input and output devices may include a keyboard 516, a mouse 518, and a display 520. A display adaptor 522 may interface with the communication bus 504 and the display 520 and may receive display data from the processor 502 and convert the display data into display commands for the display 520. In addition, the processor 502 may communicate over a network, for instance, the Internet, LAN, etc., through a network adaptor 524.

It will be apparent to one of ordinary skill in the art that other known electronic components may be added or substituted in the computer system 500. In addition, the computer system 500 may include a system board or blade used in a rack in a data center, a conventional “white box” server or computing device, etc. Also, one or more of the components in FIG. 5 may be optional (for instance, user input devices, secondary memory, etc.).

What has been described and illustrated herein is a preferred embodiment of the invention along with some of its variations. The terms, descriptions and figures used herein are set forth by way of illustration only and are not meant as limitations. Those skilled in the art will recognize that many variations are possible within the spirit and scope of the invention, which is intended to be defined by the following claims—and their equivalents—in which all terms are meant in their broadest reasonable sense unless otherwise indicated.

What is claimed is:

1. A data center comprising:
a mobile enclosure having an interior space, said interior space including:
a first section and a second section, wherein the first section is separated from the second section by a first divider, said first section housing:
a rack having a first side and a second side, wherein the rack is positioned to separate the first section into a first aisle and a second aisle such that fluid flow between the first aisle and the second aisle is substantially prevented other than through the rack;
the first aisle including a fluid delivery device, wherein the fluid delivery device is positioned in the first divider; and
the second aisle including a fluid removal device positioned in the first divider, wherein the second section facilitates fluid communication between the fluid removal device and the fluid delivery device.

2. The data center according to claim 1, further comprising:
a plurality of heat generating components housed in the rack; and
a heat exchanger configured to cool fluid flow supplied to the plurality of heat generating components, said heat exchanger having a conduit containing a cooling medium for cooling the fluid flow, said conduit being configured to fluidly connected to an apparatus for cooling the cooling medium.

3. The data center according to claim 2, further comprising:
a fan configured to circulate cooling fluid flow between the plurality of heat generating components and the heat exchanger.

4. The data center according to claim 1, further comprising:
a plurality of heat generating components housed in the rack; and
a fan for circulating cooling fluid flow from the second aisle to the first aisle by causing the fluid to flow from the fluid delivery device, through the heat generating components, through the fluid removal device, through the second section and back through the fluid delivery device.

5. The data center according to claim 4, wherein the plurality of heat generating components comprise the fan, and wherein the fans of the plurality of heat generating devices operate to circulate the cooling fluid flow.

6. The data center according to claim 1, wherein the interior space is sufficiently large for human access, said data center further comprising:
a second divider positioned to separate the first section into a third section, wherein the second section separates an upper area of the first section and the third section separates a lower area of the first section, wherein the second divider includes a fluid delivery device in the first aisle and a fluid removal device in the second aisle.

7. The data center according to claim 1, further comprising:
at least one of an ambient airflow delivery device positioned to enable ambient airflow introduction into the interior space and an airflow removal device positioned to enable removal of a mixture of cooling fluid and ambient airflow from the interior space.

8. The data center according to claim 7, further comprising:
an ambient air cooling system configured to cool the ambient airflow prior to being supplied through the ambient airflow delivery device.

9. The data center according to claim 1, further comprising:
a cooling management system having a controller configured to control an actuator to manipulate one or more environmental conditions in the mobile enclosure.

10. A data center comprising:
a mobile enclosure having an interior space, said interior space including:
a first section and a second section, wherein the first section is separated from the second section by a divider, said first section housing:
a rack having a first side and a second side, wherein the rack is positioned to separate the first section into a first aisle and a second aisle;
the first aisle including an air delivery device, wherein the air delivery device is positioned in the divider; and
the second aisle including an air removal device;
said second section including an opening for receiving ambient airflow;
a cooling apparatus configured to supply the ambient airflow through the opening, said cooling apparatus having a device for spraying fluid into the ambient airflow.

11. The data center according to claim 10, wherein the interior space is sufficiently large for human access, said data center further comprising:
a heat pipe having a first end and a second end, said first end being positioned in a path of the ambient airflow and the second end being positioned in a path of airflow exhausted through the air removal device.

12. The data center according to claim 11, further comprising:
a device for spraying fluid onto the second end of the heat pipe.

13. A method for deploying a data center, said method comprising:
providing a movable enclosure having at least one door;
positioning a divider to split an interior of the enclosure into a first section and a second section, said divider having a fluid delivery device positioned near a first end of the divider and a fluid removal device positioned on a second end of the divider; and
positioning a rack in the first section, said rack separating the first section into a first aisle and a second aisle such that fluid flow from the first aisle to the second aisle is substantially prevented other than through the rack, and wherein the fluid delivery device is positioned in the first aisle and the fluid removal device is positioned in the second aisle, such that the second section facilitates fluid communication between the fluid removal device and the fluid delivery device.

14. The method according to claim 13, further comprising:
placing a plurality of components in the rack; and
positioning a cooling system component in the enclosure, said cooling system component being configured to at least one of cool a cooling fluid contained in the enclosure and cause the cooling fluid to flow from the first aisle to the second aisle through the plurality of components.

15. The method according to claim 13, further comprising:
providing an ambient air cooling system to cool ambient airflow supplied to the first aisle.
